(19) United States
(12) Patent Application Publication
(10) Pub. No.: US 2014/0085742 A1
(43) Pub. Date: Mar. 27, 2014

(54) COLOR FILTER SUBSTRATE AND FABRICATION METHOD THEREOF, TRANSFLECTIVE LIQUID CRYSTAL DISPLAY DEVICE

(71) Applicant: BOE TECHNOLOGY GROUP CO., LTD., Beijing (CN)

(72) Inventors: Yonglian QI, Beijing (CN); Can WANG, Beijing (CN); Guanbao HUI, Beijing (CN); Jianshe XUE, Beijing (CN)

(73) Assignee: BOE TECHNOLOGY GROUP CO., LTD., Beijing (CN)

(21) Appl. No.: 13/947,687

(22) Filed: Jul. 22, 2013

(30) Foreign Application Priority Data
Sep. 27, 2012 (CN) 201210365824.X

(51) Int. Cl. G02B 5/22; G03F 7/00; G02F 1/1335

(52) U.S. Cl. CPC G02B 5/22; G02F 1/133514; G03F 7/0007
USPC 359/891; 430/321

(57) ABSTRACT

A color filter substrate and a fabrication method thereof, and a transflective liquid crystal display device are provided. The color filter substrate comprises: a transparent base substrate; a plurality of separators formed on a surface of the transparent base substrate and separating the surface of the transparent base substrate into a plurality of color filter regions; a plurality of color filter patterns that arrange alternatively with the separators, wherein each color filter pattern covers one color filter region; an aperture formed in the color filter pattern on at least one of the color filter regions; a flat protective layer at least disposed on the color filter pattern and the aperture, wherein an upper surface of a portion of the flat protective layer above the color filter pattern is even with an upper surface of a portion of the flat protective layer above the aperture.

### TECHNICAL FIELD

Embodiments of the present invention relate to a color filter substrate and a fabrication method thereof, and a transflective liquid crystal display device comprising the color filter substrate.

### BACKGROUND

As liquid crystal display is a non-self-luminous display, the liquid crystal display panel must be provided with a light source such as backlight, front light or external light source in order to display images. In accordance with different ways of using the light source, the liquid crystal display is divided into three kinds of transmissive liquid crystal display, reflective liquid crystal display and transflective liquid crystal display. Currently, the transflective liquid crystal display gets more concern as it can simultaneously use light from the external light source and the backlight, which is helpful for application in portable products.

The normal transflective liquid crystal display includes a color filter substrate, and a color filter layer is provided on the color filter substrate. The transflective liquid crystal display includes a transmissive region and a reflective region, wherein the reflective region has a reflecting electrode or a reflecting layer for reflecting light from the external light source. The light from outside is incident on the reflecting electrode or reflecting layer through the color filter layer, and the light reflected by the reflecting electrode or reflecting layer returns to outside through the color filter layer, that is, the light runs through the color filter layer twice. In contrast, the light in the transmissive region is emitted from the backlight and runs through the color filter layer only once. Therefore, colors displayed in the reflective region and the transmissive region of the transflective liquid crystal display device may be incongruous.

To solve the problem described above, an aperture may be provided in the color filter pattern corresponding to the reflective region in the color filter layer. The light from outside is incident into the reflective region via the aperture, and the reflecting electrode or reflecting layer disposed in the reflective region has a diffuse reflection effect. The light underwent the diffuse reflection by the reflecting electrode or reflecting layer is incident on the color filter pattern around the aperture, so in the reflective region, the incident light runs through the color filter layer only once and then is emitted to outside. Thereby, the problem that colors displayed in the reflective region and the transmissive region are incongruous can be alleviated. In addition, the process of providing the aperture in the color filter pattern corresponding to the reflective region in the color filter layer is easy and simple. However, after coating a flat protective layer on the color filter layer, the aperture becomes a pit 440, as shown in FIG. 1. In order to reduce the depth of the pit, the conventional method is to increase the thickness of the flat protective layer. Within a certain range, the depth of the pit decreases as the thickness of the flat protective layer increases. However, after the thickness of the flat protective layer increases to a certain degree, the depth of the pit will not decrease along with the increase of the thickness of the flat protective layer. The presence of the pit causes the flat protective layer not able to be completely flat, so that the cell gap is uneven after the cell assembly process of the transflective liquid crystal display is performed, resulting in the issues of grayscale deflection, reduction of reflectivity of the reflective region and the like.

### SUMMARY

According to one embodiment of the present invention, a color filter substrate is provided. The color filter substrate comprises: a transparent base substrate; a plurality of separators formed on a surface of the transparent base substrate and separating the surface of the transparent base substrate into a plurality of color filter regions; a plurality of color filter patterns that arrange alternatively with the separators, wherein each color filter pattern covers one color filter region; an aperture formed in the color filter pattern on at least one of the color filter regions; a flat protective layer at least disposed on the color filter pattern and the aperture, wherein an upper surface of a portion of the flat protective layer above the color filter pattern is even with an upper surface of a portion of the flat protective layer above the aperture.

For example, the color filter substrate further comprises a columnar spacer disposed above the separator, and an upper surface of the columnar spacer is higher than an upper surface of the flat protective layer.

For example, the columnar spacer and the flat protective layer are integrally formed.

For example, the separator is a photoresist separator or a black matrix.

According to another embodiment of the present invention, a fabrication method of a color filter substrate is provided. The method includes steps of:
forming a plurality of separators on a surface of a transparent base substrate, wherein the separators separate the surface of the transparent base substrate into a plurality of color filter regions;
forming a plurality of color filter patterns that arrange alternatively with the separators, wherein each color filter pattern covers one color filter region;
forming an aperture in the color filter pattern on at least one of the color filter regions;
forming a photoresist layer covering the separators, the color filter patterns and the aperture; and
performing exposing and developing processes on the photoresist layer through a dual-tone mask to form a flat protective layer at least disposed on the color filter pattern and the aperture,
wherein an upper surface of a portion of the flat protective layer above the color filter pattern is even with an upper surface of a portion of the flat protective layer above the aperture.

For example, at the same time of performing exposing and developing processes on the photoresist layer through a dual-tone mask, a columnar spacer disposed above the separator is also formed. An upper surface of the columnar spacer is higher than an upper surface of the flat protective layer.

For example, the photoresist over the separator is completely exposed with a complete exposure amount of A, an exposure amount for exposing the photoresist over the color filter pattern is H4/H3×A, and an exposure amount for exposing the photoresist over the aperture is (H2+H4)/H3×A, where H2 is a thickness of the color filter pattern, H3 is a thickness of the photoresist over the separator, H4 is a thickness of the portion of the flat protective layer above the color filter pattern, and H2+H4 is a thickness of the portion of the flat protective layer above the aperture.

For example, the separator is a photoresist separator or a black matrix.

According to still another embodiment of the present invention, a transflective liquid crystal display device is provided. The transflective liquid crystal display device comprises the color filter substrate as described above.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematic diagram of pits present on a flat protective layer in a conventional color filter substrate;

FIG. 2 is a schematic diagram after forming a separator, a color filter pattern and an aperture in a fabrication method of a color filter substrate according to a first embodiment of the present invention;

FIG. 3 is a schematic diagram after forming a photoresist layer covering the separator, the color filter pattern and the aperture in the fabrication method of the color filter substrate according to the first embodiment of the present invention;

FIG. 4 is a schematic diagram of a color filter substrate comprising a fiat protective layer after performing exposing and developing processes on the photoresist layer through a dual-tone mask in the fabrication method of the color filter substrate according to the embodiment of the present invention;

FIG. 5 is a partially enlarged view of the color filter substrate shown in FIG. 4.

FIG. 6 is a schematic diagram of a color filter substrate comprising a columnar spacer and a flat protective layer after performing exposing and developing processes on the photoresist layer through a dual-tone mask in the fabrication method of the color filter substrate according to the embodiment of the present invention.

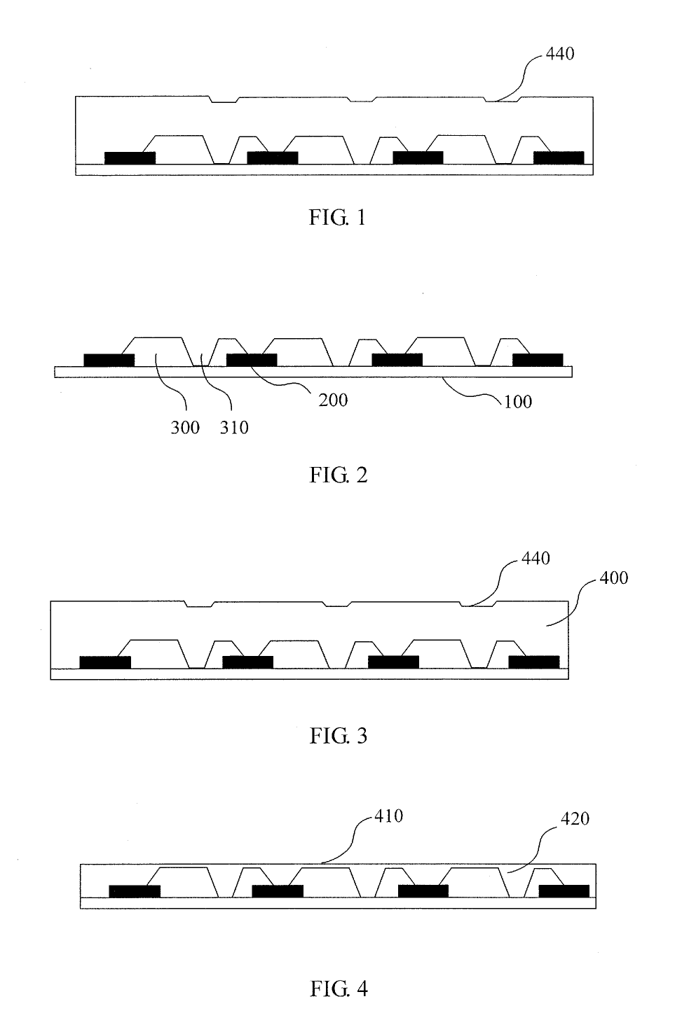

### DETAILED DESCRIPTION

In order to make objects, technical details and advantages of the embodiments of the invention apparent, the technical solutions of the embodiment will be described in a clearly and completely understandable way in connection with the drawings related to the embodiments of the invention. It is obvious that the described embodiments are just a part but not all of the embodiments of the invention. Based on the described embodiments herein. those skilled in the art can obtain other embodiment(s), without any inventive work, which should be within the scope of the invention.

A first embodiment of the present invention provides a fabrication method of a color filter substrate. The method comprises steps of:

Forming a plurality of separators on a surface of a transparent base substrate, wherein the separators are used for separating the surface of the transparent base substrate into a plurality of color filter regions;

Forming a plurality of color filter patterns that arrange alternatively with the separators, wherein each color filter pattern covers one color filter region;

Forming an aperture in the color filter pattern on at least one of the color filter regions; at this time, as shown in FIG. 2, the separators 200, the color filter patterns 300 and the apertures 310 are formed on the transparent base substrate 100;

Forming a photoresist layer covering the separators, the color filter patterns and the aperture; at this time, as shown in FIG. 3, a pit 440 is formed on a portion of the photoresist layer 400 corresponding to the aperture;

Performing exposing and developing processes on the photoresist layer 400 through a dual-tone mask such as a gray-tone mask to form a flat protective layer; at this time, as shown in FIG. 4, the photoresist layer after the exposing and developing processes forms a flat protective layer. The flat protective layer includes a portion 410 located above the color filter pattern and a portion 420 located above the aperture. An upper surface of the portion 410 of the flat protective layer above the color filter pattern is even with an upper surface of the portion 420 of the flat protective layer above the aperture.

In the fabrication method of the color filter substrate according to the present embodiment, the flat protective layer is formed by performing exposing and developing processes on the photoresist layer, and the upper surface of the portion of the flat protective layer above the color filter pattern is even with the upper surface of the portion of the flat protective layer above the aperture, so that the problem that the flat protective layer of the conventional color filter substrate has pits is solved.

Further, at the same time of performing exposing and developing processes on the photoresist layer through a dual-tone mask such as a gray-tone mask, a columnar spacer 430 above the separator may also be formed, and an upper surface of the columnar spacer 430 is higher than an upper surface of the flat protective layer. In this way, the columnar spacer and flat protective layer can be obtained by one patterning process, and thus the conventional manufacturing process for the columnar spacer can be omitted.

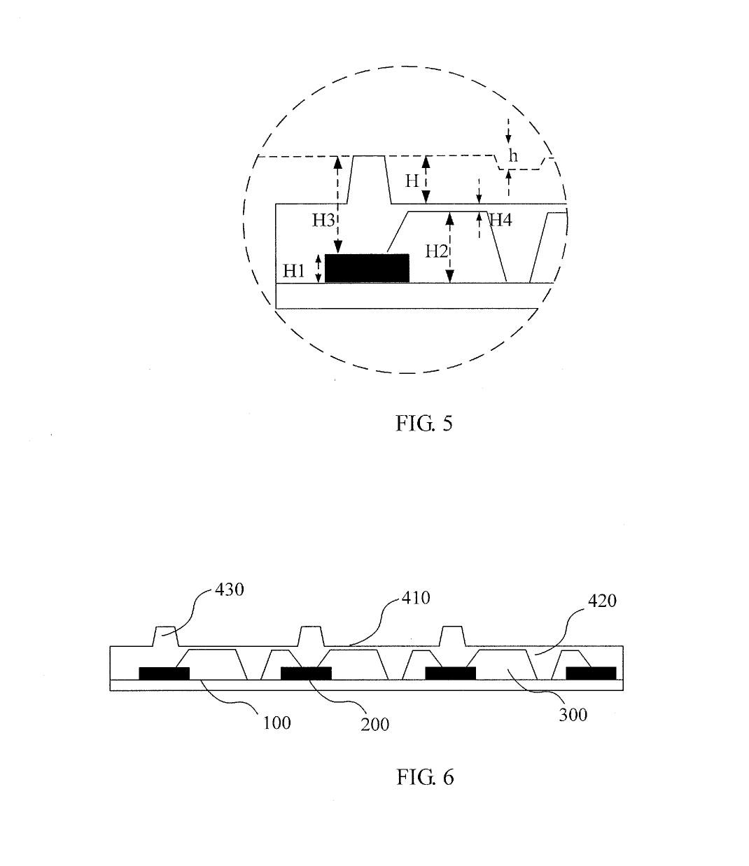

For example, the photoresist is a positive photoresist. The photoresist over the separator is completely exposed, an exposure amount for exposing the photoresist over the color filter pattern is equal to H4/H3×A, and an exposure amount for exposing the photoresist over the aperture is equal to (H2+H4)/H3×A, where A is an exposure amount of complete exposure. As shown in FIG. 5, H1 is a thickness of the separator, H2 is a thickness of the color filter pattern, H3 is a thickness of the photoresist over the separator, H4 is a thickness of the portion 410 of the flat protective layer above the color filter pattern, and H2+H4 is a thickness of the portion 420 of the flat protective layer above the aperture.

After the exposing and developing processes, the height of the removed photoresist over the color filter pattern H=H1+H3−(H2+H4), and H>h, where h is the depth of the pit. That is to say, the height of the removed photoresist over the color filter pattern is greater than the depth of the pit.

In the fabrication method of the color filter substrate according to the present embodiment, with a precise control of the exposure amount for exposing the photoresist over the color filter pattern and the exposure amount for exposing the photoresist over the aperture, the columnar spacer, the portion of the flat protective layer above the color filter pattern with the thickness of H4, and the portion of the flat protective layer above the aperture with the thickness of H2+H4 are obtained through one single patterning process. Thus, the pits in the flat protective layer of the conventional color filter substrate are eliminated. Meanwhile, the columnar spacer and the flat protective layer are obtained through one single patterning process, and thus the fabrication process for the color filter substrate can be simplified.

The separator may be a photoresist separator or a black matrix. However, the form of the separator is not limited to the types listed above, and the separator can adopt any other forms as long as it can separate the surface of the transparent base substrate into the plurality of color filter regions.

A specific example will be described below with reference to FIG. 5.

For example, the thickness of the separator is H1=1 μm the thickness of the color filter pattern is H2=1.5 μm, the thickness of the photoresist over the separator is H3=4.5 μm, and the depth of the pit is h=0.5 μm.

For example, it is required the thickness of the portion 410 of the flat protective layer above the color filter pattern to be H4=1.5 μm, and the thickness of the portion 420 of the flat protective layer above the aperture to be H2+H4=1.5 μm+1.5 μm=3 μm.

The photoresist over the separator is completely exposed with an exposure amount of A, and all the photoresist over the separator with the thickness of 4.5 μm is used to form the columnar spacer.

The thickness of the portion 410 of the flat protective layer above the color filter pattern is H4=1.5 μm, that is, the portion 410 of the flat protective layer above the color filter pattern with the thickness of 1.5 μm is formed after the photoresist above the color filter pattern is exposed and developed. The exposure amount for exposing the photoresist above the color filter pattern is H4/H3×A=1.5/4.5×A=1/3×A.

The thickness of the portion 420 of the flat protective layer above the aperture is H2+H4=3 μm, that is, the portion 420 of the flat protective layer above the aperture with the thickness of 3 μm is formed after the photoresist above the aperture is exposed and developed. The exposure amount for exposing the photoresist above the aperture is (H2+H4)/H3×A=3/4.5×A=2/3×A.

A second embodiment of the present invention provides a color filter substrate. The color filter substrate is obtained by the fabrication method according to the first embodiment.

As shown in FIG. 6, the color filter substrate comprises: a transparent base substrate 100; a plurality of separators 200 formed on a surface of the transparent base substrate and separating the surface of the transparent base substrate into a plurality of color filter regions; a plurality of color filter patterns 300 that arrange alternatively with the separators 200, wherein each color filter pattern covers one color filter region; an aperture formed in the color filter pattern on at least one of the color filter regions; a flat protective layer at least disposed on the color filter pattern and the aperture, wherein an upper surface of a portion 410 of the flat protective layer above the color filter pattern is even with an upper surface of a portion 420 of the flat protective layer above the aperture.

In the color filter substrate according to the present embodiment, the upper surface of the portion 410 of the flat protective layer above the color filter pattern is even with the upper surface of the portion 420 of the flat protective layer above the aperture, thereby the problem that the pits cause the flat protective layer unable to be completely flat in the conventional technology can be solved.

For example, as shown in FIG. 6, the color filter substrate according to the present embodiment further comprises a columnar spacer 430 disposed above the separator 200, and an upper surface of the columnar spacer 430 is higher than an upper surface of the flat protective layer.

For example, the columnar spacer and the flat protective layer are integrally formed. When the columnar spacer and the flat protective layer are integrally formed, the columnar spacer can be firmly fixed, thus uneven display effect caused by dislocation of the columnar spacer can be prevented.

For example, the separator is a photoresist separator or a black matrix.

A third embodiment of the present invention provides a transflective liquid crystal display device. The transflective liquid crystal display device comprises an array substrate and a color filter substrate, wherein the color filter substrate is the color filter substrate according to the second embodiment of the present invention.

The transflective liquid crystal display device employs the color filter substrate according to the second embodiment, so that the cell gap of the transflective liquid crystal display device is uniform after the cell assembly process of the transflective liquid crystal display is performed. Therefore, the possibilities of grayscale deflection, reduction of reflectivity of the reflective region and other issues can be reduced.

The foregoing embodiments merely are exemplary embodiments of the invention, and not intended to define the scope of the invention, and the scope of the invention is determined by the appended claims.

What is claimed is:

1. A color filter substrate, comprising:
a transparent base substrate;
a plurality of separators formed on a surface of the transparent base substrate and separating the surface of the transparent base substrate into a plurality of color filter regions;
a plurality of color filter patterns that arrange alternatively with the separators, wherein each color filter pattern covers one color filter region;
an aperture formed in the color filter pattern on at least one of the color filter regions;
a flat protective layer at least disposed on the color filter pattern and the aperture,
wherein an upper surface of a portion of the flat protective layer above the color filter pattern is even with an upper surface of a portion of the flat protective layer above the aperture.

2. The color filter substrate according to claim 1, wherein the color filter substrate further comprises a columnar spacer disposed above the separator, and an upper surface of the columnar spacer is higher than an upper surface of the flat protective layer.

3. The color filter substrate according to claim 2, wherein the columnar spacer and the flat protective layer are integrally formed.

4. The color filter substrate according to claim 1, wherein the separator is a photoresist separator or a black matrix.

5. A fabrication method of a color filter substrate, comprising steps of:
forming a plurality of separators on a surface of a transparent base substrate, wherein the separators separate the surface of the transparent base substrate into a plurality of color filter regions;
forming a plurality of color filter patterns that arrange alternatively with the separators, wherein each color filter pattern covers one color filter region;
forming an aperture in the color filter pattern on at least one of the color filter regions;
forming a photoresist layer covering the separators, the color filter patterns and the aperture: and
performing exposing and developing processes on the photoresist layer through a dual-tone mask to form a flat protective layer at least disposed on the color filter pattern and the aperture,
wherein an upper surface of a portion of the flat protective layer above the color filter pattern is even with an upper surface of a portion of the flat protective layer above the aperture.

6. The fabrication method of a color filter substrate according to claim 5, wherein at the same time of performing exposing and developing processes on the photoresist layer through a dual-tone mask, a columnar spacer disposed above the separator is also formed, and
an upper surface of the columnar spacer is higher than an upper surface of the flat protective layer.

7. The fabrication method of a color filter substrate according to claim 6, wherein the photoresist over the separator is completely exposed with a complete exposure amount of A, an exposure amount for exposing the photoresist over the color filter pattern is H4/H3×A, and an exposure amount for exposing the photoresist over the aperture is (H2+H4)/H3×A, where H2 is a thickness of the color filter pattern, H3 is a thickness of the photoresist over the separator, H4 is a thickness of the portion of the flat protective layer above the color filter pattern, and H2+H4 is a thickness of the portion of the flat protective layer above the aperture.

8. The fabrication method of a color filter substrate according to claim 5, wherein the separator is a photoresist separator or a black matrix.

9. A transflective liquid crystal display device, comprising the color filter substrate according to claim 1.
